(19) United States
(12) Patent Application Publication
(10) Pub. No.: US 2020/0211903 A1
(43) Pub. Date: Jul. 2, 2020

(54) SEMICONDUCTOR STRUCTURE WITH SHAPED TRENCH AND METHODS OF FORMING THE SAME

(71) Applicant: GLOBALFOUNDRIES INC., Grand Cayman (KY)

(72) Inventors: JIEHUI SHU, Clifton Park, NY (US); JESSICA MARY DECHENE, Watervliet, NY (US); HUI ZANG, Guilderland, NY (US); NAVED AHMED SIDDIQUI, Latham, NY (US)

(21) Appl. No.: 16/237,757

(22) Filed: Jan. 2, 2019

(51) Int. Cl. H01L 21/8234; H01L 27/088; H01L 29/66; H01L 21/308

(52) U.S. Cl. CPC H01L 21/823437; H01L 27/0886; H01L 21/308; H01L 21/823431; H01L 21/823481; H01L 29/66545

(57) ABSTRACT

The present disclosure generally relates to semiconductor device fabrication and integrated circuits. More particularly, the present disclosure relates to methods of forming a two-part trench in a semiconductor device that includes one or more field-effect transistors (FETs). The present method includes forming a semiconductor layer above a substrate, forming a mask layer above the semiconductor layer, forming a mask opening with sidewalls in the mask layer and exposing the semiconductor layer, depositing a profile control layer on the sidewalls of the mask opening, and forming a trench in the semiconductor layer by simultaneously etching the profile control layer and the exposed semiconductor layer, where the etching of the profile control layer forms the trench with top and bottom sections having different widths.

### FIELD OF THE INVENTION

The present disclosure generally relates to semiconductor device fabrication and integrated circuits. More particularly, the present disclosure relates to methods of forming a two-part trench in a semiconductor device that includes one or more field-effect transistors (FETs). The present disclosure also relates to a semiconductor structure with a shaped trench formed by the methods disclosed herein.

### BACKGROUND

In integrated circuit (IC) design, as the number of devices per chip increases, both inter and intra device dimensions decrease. The demand within the semiconductor industry for high density, high performance, and low cost devices and the implementation of nanometer-scale process nodes have resulted in the development of three-dimensional (3D) architectures such as a fin-shaped field effect transistor (FinFET). Within a typical FinFET, the channel between the source and the drain is formed as a raised fin over a substrate. The gate electrode is then formed over the sidewalls and top of the channel.

In some FinFET technologies, a gate cut is performed to interrupt the continuity of a dummy gate in order to divide the dummy gate into segments. The gate cut may produce a trench within the dummy gate and the trench is then filled with a dielectric material. The segmentation is reproduced with the dummy gate being replaced with a replacement metal gate (i.e., the gate electrode).

As fin pitch scales downward, forming the gate cut between the fin and the trench becomes increasingly challenging with respect to process margin limitations. Due to small sizing of this gate cut, conventional gate cut patterning and etching process may cause incomplete removal of the dummy gate material during subsequent replacement metal gate processes, which may reduce yield and cause electrical shorting between adjacent fins. In addition, conventional gate cut processes may also cause incomplete filling by the replacement metal gate material due to small fin-to-trench dimensions, which may result in increased defect occurrence in the device. One possible technique to avoid the drawbacks of decreasing the size of the gate cut is to increase the fin-to-trench dimensions by narrowing the trenches for dielectric material while maintaining the downward scaling of the device. However, the trenches formed by this approach are found to be overly narrow, and gate cut processes to produce such narrow trenches encountered increased process difficulties and required higher process cost.

Therefore, there is a need to provide methods of forming a semiconductor structure that can overcome, or at least ameliorate, one or more of the disadvantages as described above.

### SUMMARY

In one aspect of the present disclosure, there is provided a method of forming a structure in a semiconductor device by forming a semiconductor layer above a substrate, forming a mask layer above the semiconductor layer, forming a mask opening with sidewalls in the mask layer and exposing the semiconductor layer, depositing a profile control layer on the sidewalls of the mask opening, and forming a trench in the semiconductor layer by simultaneously etching the profile control layer and the exposed semiconductor layer, where the etching of the profile control layer forms the trench with top and bottom sections having different widths.

In another aspect of the present disclosure, there is provided a method of forming a structure in a semiconductor device by forming a dummy gate above a plurality of fins, forming a mask layer above the dummy gate, forming a mask opening with sidewalls in the mask layer and exposing the dummy gate, depositing a profile control layer on the sidewalls of the mask opening, and forming a gate cut trench in the dummy gate by performing a gate cut process simultaneously on the profile control layer and the exposed dummy gate, where the gate cut process includes etching the profile control layer on the sidewalls to form the gate cut trench with top and bottom sections having different widths.

In yet another aspect of the present disclosure, there is provided a semiconductor structure including a semiconductor material disposed above a plurality of fins, a gate cut trench formed in the semiconductor material, the gate cut trench having a top section, a transitional medial section and a bottom section, and the bottom section is narrower than the top section, the transitional medial section is proximally above top edges of the plurality of fins.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of well-known features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

FIGS. 1A and 1B are drawings that illustrate a top down view and a cross section view (taken along line X-X′ as indicated in FIG. 1A), respectively, of a set of device elements for forming a structure in a semiconductor device in accordance with embodiments of the present disclosure.

FIGS. 2-4B are schematic cross section views at various stages of forming a structure in a semiconductor device in accordance with embodiments of the present disclosure.

FIGS. 5A and 5B are drawings that illustrate top down and cross section views respectively of a semiconductor device structure formed in accordance with embodiments of the present disclosure.

### DETAILED DESCRIPTION

Various illustrative embodiments of the present disclosure are described below. The embodiments disclosed herein are exemplary and not intended to be exhaustive or limiting to the present disclosure.

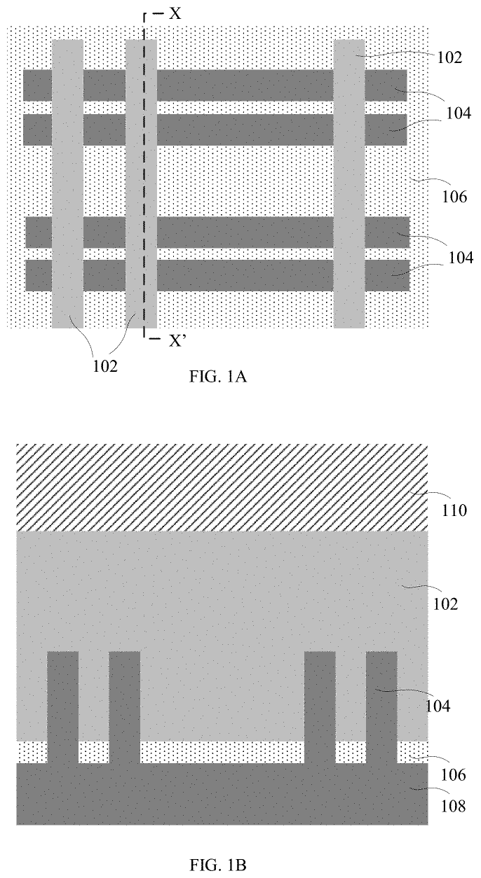

Referring to FIG. 1A, a top down view of a set of device elements for forming a semiconductor device structure in accordance with the present disclosure is shown. Although FIG. 1A illustrates one set of device elements targeted for use with embodiments of the present disclosure, it is understood that embodiments of the present disclosure can be implemented on different designs without any change to the techniques discussed herein. The device elements shown in FIG. 1A may be formed by suitable semiconductor fabrication processes. The device elements may include a substrate (not shown in FIG. 1A), a plurality of fins 104 formed on the substrate, and one or more semiconductor layers (e.g., layers, gates, etc.) 102 laterally disposed above the fins 104. A shallow trench isolation region 106 may be formed on the substrate. Although not shown in FIG. 1A, a mask layer may be disposed on the semiconductor layers 102. In some embodiments, the semiconductor layer 102 is a dummy gate. Although not shown in the accompanying drawings, the dummy gate may include dummy gate spacers formed on sidewalls of the dummy gate.

Referring to FIG. 1B, a mask layer 110 is formed on the semiconductor layer 102 of the semiconductor device shown in FIG. 1A. The mask layer 110 may be formed by conventional deposition processes. As used herein, the term “deposition processes” generally refers to the process of applying a material over another material (or the substrate). Exemplary techniques for deposition include, but not limited to, chemical vapour deposition (CVD), physical vapor deposition (PVD), sputtering, or spin-coating. The mask layer 110 may include a dielectric material such as silicon carbide, silicon dioxide, silicon nitride, silicon oxynitride, titanium oxide, titanium nitride, aluminum oxide, hafnium oxide. In some embodiments, the mask layer 110 is a gate mask.

As shown in FIG. 1B, each fin 104 is separated by the shallow trench isolation region 106. The shallow isolation trenches 106 may include any suitable dielectric material, such as silicon dioxide or silicon nitride. The fins 104 may include any suitable semiconductor material, such as silicon, germanium, or silicon germanium. In one embodiment, the semiconductor material used for the fin is silicon. Although not shown in the drawings, the fins may have additional epitaxial semiconductor material formed thereon in either a merged or unmerged condition and may function as source/drain regions.

The substrate 108 may be made of any suitable semiconductor material, such as silicon, germanium, silicon germanium (SiGe), silicon/carbon, other II-VI or III-V semiconductor compounds and the like. The substrate 108 may also include an organic semiconductor or a layered semiconductor, such as Si/SiGe, a silicon-on-insulator or a SiGe-on-insulator. In one embodiment, the substrate 108 includes silicon.

As shown in FIG. 1B, the semiconductor layer 102 may be deposited on the fins 104 and the shallow trench isolation regions 106. The semiconductor layers 102 may include, but not limited to, a dielectric material, silicon, germanium, polysilicon, amorphous silicon, amorphous carbon, and combinations thereof. In one embodiment, the semiconductor layer 102 includes amorphous silicon.

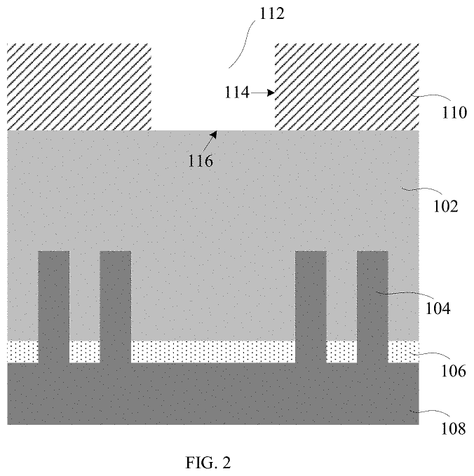

FIG. 2 illustrates an example of forming a mask opening 112 in the mask layer 110 in accordance with embodiments of the present disclosure. The formed mask opening 112 includes sidewalls 114 and may be formed using conventional patterning techniques. The formation of the mask opening 112 exposes a top surface 116 of the semiconductor layer 102.

As used herein, the term “patterning techniques” includes, but not limited to, wet etch lithographic processes, dry etch lithographic processes or direct patterning processes. Here, the term “processes” includes deposition of material or photoresist, patterning, exposure, development, etching, cleaning, and/or removal of the material or photoresist as required in forming a described structure.

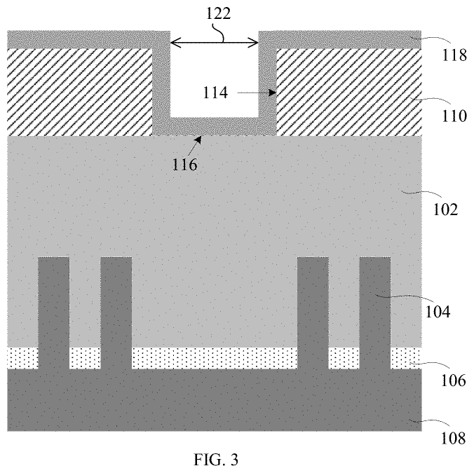

FIG. 3 illustrates an example of forming a profile control layer 118, including on the sidewalls 114 of the mask opening 112 and the exposed top surface 116 of the semiconductor layer 102, in accordance with embodiments of the present disclosure. The profile control layer 118 may be formed by any conventional deposition process. However, a highly conformal deposition process is preferred for depositing the profile control layer 118; for example, ALD process or highly-controlled CVD process. The deposition of the profile control layer 118 covers the mask layer 110, as well as in the mask opening. The deposition of the profile control layer 118 on the sidewalls 114 forms a profile control spacing 122 in the mask opening, as shown in FIG. 3. The profile control spacing 122 is defined as the width between deposited profile control layers 118 on opposing sidewalls of the mask opening 112. In one embodiment, the profile control spacing 122 has a width in the range of about 5 nm to about 30 nm. Alternatively, the deposition of the profile control layer 118 in the mask opening may be non-conformal. In an alternative embodiment (not shown), the profile control layer 118 is deposited only on the sidewalls 114, leaving the top surface 116 exposed.

In another embodiment (not shown), the thickness of the profile control layer 118 deposited on the sidewalls 114 is different from the thickness of the profile control layer 118 deposited on the top surface 116 of the semiconductor layer 102. However, the formed profile control layer 118 on the sidewalls 114 and the top surface 116 are individually uniform, albeit different in their thicknesses. In another embodiment, the preferred thickness of the deposited profile control layer is in the range of about 5 nm to about 25 nm. The thickness of the deposited profile control layer 118 may be determined based on the profile control spacing 122. For example, if a narrower dimension for the profile control spacing 122 is desired, then the amount of material deposited for the profile control layer 118 can be increased such that the profile control layer 118 has a larger thickness.

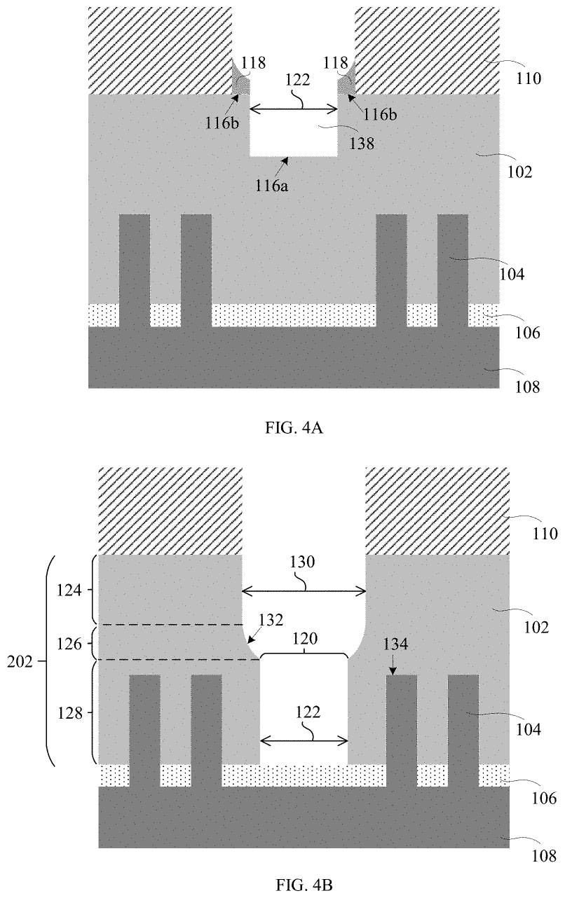

FIGS. 4A-4B are cross section views depicting successive processing stages of the semiconductor device, as shown in FIG. 3, in accordance with the present disclosure. An etching process is performed to form a trench in the semiconductor layer 102. The etching process includes simultaneous etching of the profile control layer 118 and the semiconductor layer 102. Advantageously, the profile control layer 118 is used to control the etch rate of the semiconductor layer 102 and the profile (i.e., shape) thereof. More advantageously, the etching of the profile control layer 118 enables the formation of a trench with top and bottom sections having different widths.

In one embodiment, the etching process is performed directly after forming the profile control layer 118. The etching process may be performed using suitable etching techniques, such as reactive ion etching (ME), or physical etching (e.g., ion beam induced etching, ion milling). In some embodiments, the etching process includes a gate cut process. The gate cut process may be performed to cut dummy gates in the cross direction to separate FinFET devices.

FIG. 4A shows an intermediary illustration of the device elements between the processing stages of FIG. 3 and FIG. 4B. Referring to FIG. 4A, the “flat” portions of the profile control layer previously deposited on the top surfaces of mask layer 110 and the exposed semiconductor layer have been simultaneously removed during the etching process. At the same time, the portion of the profile control layer deposited on the sidewalls of the mask opening is partially removed. Accordingly, there may be residual portions of the profile control layer 118 remaining on the sidewalls of the mask opening, as shown in FIG. 4A.

The etching process recesses the surface 116 of the semiconductor layer 102, while simultaneously etching the remaining profile control layer 118 on the sidewalls of the mask opening. The etching of the semiconductor layer 102 forms an opening 138 in the semiconductor layer 102, and the partial top surface 116a is formed by the opening 138. The profile control spacing 122 is maintained during etching of the semiconductor layer 102, i.e., the etching process includes transferring the profile control spacing 122 to have a width for the opening 138 in the semiconductor layer 102 that is substantially the same, as shown in FIG. 4A.

Although not shown in FIG. 4A, the etching process, as it proceeds, completely removes the residual profile control layer 118 on the sidewalls of the mask opening while simultaneously etching the opening 138 such that the opening 138 extends deeper into the semiconductor layer 102. The removal of the residual profile control layer 118 re-exposes a partial top surface 116b of the semiconductor layer 102. Subsequently, the etching process simultaneously recesses the second partial top surface 116b, while continuing to etch the opening 138. A trench with top and bottom sections is formed, where the top and bottom sections have different widths.

As described herein, the etching of the profile control layer 118 and the semiconductor layer 102 is simultaneous, however, the etch selectivity of the profile control layer 118 and the semiconductor layer 102 may be the same or different. In some embodiments, the semiconductor layer 102 has a higher or equal etch selectivity with respect to the profile control layer 118 depending on the selection of materials, respectively. The profile control layer 118 controls the profile of the formed trench (e.g., the relative depth and width of the top and bottom sections), in accordance with the present disclosure.

In one embodiment, the profile control layer 118 includes the same material as the semiconductor layer 102. For example, if the semiconductor layer 102 and the profile control layer 118 are both made of amorphous silicon, then the etch rates of the dummy and profile control layers (102 and 118, respectively) are the same, and the subsequently formed trench has top and bottom sections with substantially equal depth. In another embodiment, the profile control layer 118 is a different material from the semiconductor layer 102, such as an oxide containing compound, a nitride containing compound, and a metal oxide compound (e.g., titanium oxide, aluminum oxide, etc.). For example, if the semiconductor layer 102 is amorphous silicon and the profile control layer 118 is aluminum oxide, then the etching is more selective to the semiconductor layer 102 than the profile control layer 118, and the etch rate of the semiconductor layer 102 is faster than the etch rate of the profile control layer 118, thereby forming a trench with the bottom section having a larger depth than the top section.

Referring to FIG. 4B, the etching process forms a trench 202 having a top section 124 and a bottom section 128. In one embodiment, the top and bottom sections (124 and 128, respectively) are formed simultaneously by a single continuous etching process. The top section 124 transitions to the bottom section 128 through a medial section 126. The transitional medial section 126 may include sidewalls 132 having a concave profile. The bottom section 128 may have an opening 120 that is positioned above top edges 134 of the fins 104, as shown in FIG. 4B. The sidewalls 132 of the transitional medial section 126 taper towards the opening 120 of the bottom section 128. The etching process (e.g., gate cut process) may sever the semiconductor layer 102 (e.g., the dummy gate). In one embodiment, the trench 202 exposes a portion of the shallow trench isolation region 106. In some embodiments, the trench 202 is a gate cut trench.

Advantageously, by forming a gate cut trench with the bottom section being narrower than the top section, it is found to increase the process margin limitations for forming a gate cut structure by increasing fin-to-trench dimensions, while addressing the downscaling requirements of semiconductor devices. More advantageously, the increased fin-to-trench dimension is found to enable complete pull of the dummy gate in subsequent replacement metal gate processes. Also advantageously, the increased fin-to-trench dimension may enable complete filling of replacement metal gate material, thereby avoiding defects in the device.

As described herein, the bottom section 128 is narrower than the top section 124. The mask opening functions to define the width 130 of the top section 124, as shown in FIG. 4B. In one embodiment, the mask opening may have a predetermined width that is transferred to the top section width 130 during the etching process.

Advantageously, the profile control spacing 122 will control and define the width of the bottom section 128. In particular, the dimension of the profile control spacing 122 will be transferred to the width of the bottom section 128 of the formed trench 202. For example, the presence of the profile control spacing 122 during the etching process enables the width of the bottom section 128 to be narrower than the width of the top section 124. The depth of the bottom section 128 of the trench 202 may be defined by a pre-determined thickness of the mask layer 110. For example, if both the profile control layer and the semiconductor layer include the same material, then the resulting etched depth of the bottom section 128 is substantially the same as the thickness of the mask layer 110.

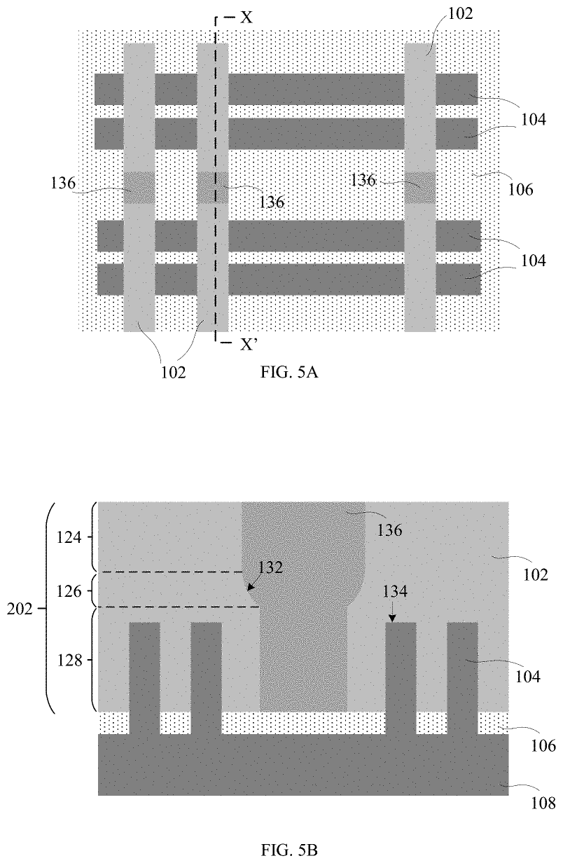

Referring to FIGS. 5A and 5B, the trench 202 is filled with a dielectric material 136 in subsequent processing stages of the present disclosure. FIG. 5B is a cross section view of FIG. 5A taken along section line X-X′. The dielectric material 136 is disposed within the trench 202 and may be filled by using conventional deposition processes. The mask layer may then be removed by polishing (e.g., chemical mechanical planarization), and the dielectric material 136 may be planar with the semiconductor layer 102. Advantageously, having a larger width in the top section of the trench may enable complete filling by the dielectric material, avoid material pinch-off and formation of voids, thereby improving device yield and decreasing processing cost.

It shall be noted that embodiments of the methods disclosed in the present disclosure may be applicable in other semiconductor processing technologies or semiconductor fabrication stages (e.g., front end of line or back end of line processes). In particular, the disclosed method of forming a trench may be applicable for forming a via opening in a semiconductor device, forming an isolation structure in a semiconductor device, or the like.

Throughout this disclosure, the terms top, upper, upwards, over, and above refer to the direction away from the substrate. Likewise, the terms bottom, lower, downwards, under, and below refer to the direction towards the plurality of fins. It is to be understood that the terms so used are interchangeable under appropriate circumstances such that the embodiments of the device described herein are, for example, capable of operation in other orientations than those illustrated or otherwise described herein.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description.

Additionally, the various tasks and processes described herein may be incorporated into a more comprehensive procedure or process having additional functionality not described in detail herein. In particular, various processes in the manufacture of integrated circuits are well-known and so, in the interest of brevity, many conventional processes are only mentioned briefly herein or omitted entirely without providing the well-known process details.

As will be readily apparent to those skilled in the art upon a complete reading of the present application, the methods of forming the semiconductor structure disclosed herein may be employed in replacement metal gate processes for forming FinFET components on a semiconductor device, and may be employed in manufacturing a variety of different integrated circuit products, including, but not limited to, logic products, memory products, complementary metal oxide semiconductor (CMOS) devices, etc.

1. A method of forming a structure in a semiconductor device comprising:
forming a semiconductor layer above a substrate;
forming a mask layer above the semiconductor layer;
forming a mask opening with sidewalls in the mask layer and exposing the semiconductor layer;
depositing a profile control layer on the sidewalls of the mask opening; and
forming a trench in the semiconductor layer by simultaneously etching the profile control layer and the exposed semiconductor layer, wherein the etching of the profile control layer forms the trench with top and bottom sections having different widths.

2. The method of claim 1, wherein the deposition of the profile control layer on the sidewalls of the mask opening forms a profile control spacing.

3. The method of claim 2, wherein the profile control spacing is transferred by the etching to become a width of the bottom section.

4. The method of claim 1, wherein the mask opening has a width that is transferred by the etching to become a width of the top section.

5. The method of claim 1, wherein the deposition of the profile control layer includes depositing on the exposed semiconductor layer.

6. The method of claim 5, wherein the simultaneous etching of the profile control layer and the exposed semiconductor layer includes removing the profile control layer deposited on the sidewalls and the semiconductor layer.

7. The method of claim 1, wherein the top and bottom sections of the trench are formed simultaneously.

8. The method of claim 1, wherein the simultaneous etching severs the semiconductor layer.

9. The method of claim 1, wherein the simultaneous etching includes the semiconductor layer having a higher or equal etch selectivity with respect to the profile control layer.

10. The method of claim 1, further comprising filling the trench with a dielectric material.

11. A method of forming a structure in a semiconductor device comprising:
forming a dummy gate above a plurality of fins;
forming a mask layer above the dummy gate;
forming a mask opening with sidewalls in the mask layer and exposing the dummy gate;
depositing a profile control layer on the sidewalls of the mask opening; and
forming a gate cut trench in the dummy gate by performing a gate cut process simultaneously on the profile control layer and the exposed dummy gate, wherein the gate cut process includes etching the profile control layer on the sidewalls to form the gate cut trench with top and bottom sections having different widths.

12. The method of claim 11, wherein the deposition of the profile control layer on the sidewalls of the mask opening forms a profile control spacing.

13. The method of claim 11, wherein the gate cut process includes forming the top and bottom sections simultaneously.

14. The method of claim 11, wherein the gate cut process stops when a transitional medial section between the top section and the bottom section is proximally above top edges of the plurality of fins.

15. The method of claim 12, wherein the profile control spacing is transferred by the gate cut process to become a width for the bottom section.

16. The method of claim 11, wherein the gate cut process severs the dummy gate.

17. The method of claim 11, further comprising filling the trench with a dielectric material.

18. A semiconductor structure comprising:
a semiconductor material disposed above a plurality of fins;
a gate cut trench formed in the semiconductor material;
the gate cut trench having a top section, a transitional medial section and a bottom section; and
the bottom section is narrower than the top section, the transitional medial section is proximally above top edges of the plurality of fins.

19. The structure of claim 18, wherein the transitional medial section includes sidewalls having a concave profile.

20. The structure of claim 18, further comprising a dielectric material disposed within the gate cut trench.

21. The structure of claim 18, wherein the transitional medial section includes sidewalls that taper towards an opening of the bottom section.

22. The structure of claim 18, wherein the gate cut trench severs the semiconductor material.

23. The structure of claim 18, wherein the semiconductor material is amorphous silicon.

24. The structure of claim 18, further comprising:
a substrate;
a shallow trench isolation region formed on the substrate, wherein the plurality of fins are being formed on the substrate and each fin is separated by the shallow trench isolation region; and
the semiconductor material is deposited on the plurality of fins and the shallow trench isolation region.

25. The structure of claim 24, wherein the gate cut trench severs the semiconductor material to expose the shallow trench isolation region.

26. A semiconductor structure comprising:
a semiconductor material disposed above a plurality of fins;
a gate cut trench formed in the semiconductor material;
the gate cut trench having a top section, a transitional medial section and a bottom section; and
the bottom section is narrower than the top section.

27. The structure of claim 26, wherein the transitional medial section includes sidewalls that taper towards an opening of the bottom section.

28. The structure of claim 27, wherein the sidewalls of the transitional medial section have a concave profile.

29. The structure of claim 28, wherein the transitional medial section is proximally above top edges of the plurality of fins.

30. The structure of claim 29, further comprising a dielectric material disposed within the gate cut trench.

31. The structure of claim 30, further comprising:
a substrate;
a shallow trench isolation region formed on the substrate, wherein the plurality of fins are being formed on the substrate and each fin is separated by the shallow trench isolation region; and
the semiconductor material is deposited on the plurality of fins and the shallow trench isolation region

32. The structure of claim 31, wherein the gate cut trench severs the semiconductor material and exposes the shallow trench isolation region.

33. The structure of claim 32, wherein the semiconductor material is amorphous silicon.
